(19) United States
(12) Patent Application Publication
(10) Pub. No.: US 2008/0314434 A1
(43) Pub. Date: Dec. 25, 2008

(54) PHOTOVOLTAIC PANEL

(76) Inventors: Bruce M. Khouri, Glendale, CA (US); Kevin D. Tabor, Lausanne (CH); Randall E. Jurisch, La Crescenta, CA (US)

Correspondence Address: CHRISTIE, PARKER & HALE, LLP, PO BOX 7068, PASADENA, CA, 91109-7068, US

(21) Appl. No.: 11/766,709

(22) Filed: Jun. 21, 2007

(51) Int. Cl. H01L 31/045

(52) U.S. Cl. 136/245; 136/251

(57) ABSTRACT

A photovoltaic panel (PV panel) includes a plurality of rigid solar or photovoltaic modules attached to a flexible membrane. The PV modules are arranged adjacent to each other, e.g., side-by-side or end-to-end, and are spaced apart from each other so as to allow each PV module to be folded over an adjacent PV module. The PV modules have wires that are arranged so as to provide connection to wires of the adjacent PV modules with wires. The wires extending between adjacent PV modules have sufficient length or slack so as to allow the modules to be folded over each other. The PV panel may include a plurality of spacers between the PV modules and the membrane to provide gaps. The gaps aid in cooling of the PV modules during operation.

### FIELD OF THE DISCLOSURE

The present disclosure relates to roofing components, panels and systems, and more particularly, to a photovoltaic panel having solar or photovoltaic modules integrated with a flexible membrane.

### BACKGROUND

Various types of roofing materials have been utilized to provide building structures protection from the sun, rain, snow and other weather and environment elements. Examples of known roofing materials include clay tiles, cedar and composition shingles and metal panels, and BUR materials, (e.g., both hot and cold applied bituminous based adhesives, emulsions and felts), which can be applied to roofing substrates such as wood, concrete and steel. Additionally, single-ply membrane materials, e.g., modified bitumen sheets, thermoplastics such as polyvinylchloride (PVC) or ethylene interpolymer, vulcanized elastomers, e.g., ethyl propylene diene (monomer) terpolymer (EPDM) and Neoprene, and non-vulcanized elastomers, such as chlorinated polyethylene, have also been utilized as roofing materials.

While such roofing materials may be satisfactory for the basic purpose of protecting a building structure from environmental elements, their use is essentially limited to these protective functions.

Solar energy has received increasing attention as an alternative renewable, non-polluting energy source to produce electricity as a substitute to other non-renewable energy resources, such as coal and oil that also generate pollution. Some building structures have been outfitted with solar panels on their flat or pitched rooftops to obtain electricity generated from the sun. These “add-on” can be installed on any type of roofing system as “stand alone” solar systems. However, such systems typically require separate support structures that are bolted together to form an array of larger solar panels. Further, the “add-on” solar panels are heavy and are more costly to manufacture, install and maintain. For example, the assembly of the arrays is typically done on-site or in the field rather than in a factory. Mounting arrays onto the roof may also require structural upgrades to the building. Additionally, multiple penetrations of the roof membrane can compromise the water-tight homogeneity of the roof system, thereby requiring additional maintenance and cost. These “add-on” solar panel systems may also be considered unsightly or an eyesore since they are attached to and extend from a roof. These shortcomings provide a barrier to more building structures being outfitted with solar energy systems which, in turn, increase the dependence upon traditional and more limited and polluting energy resources.

Other known systems have combined roofing materials and photovoltaic solar cells to form a “combination” roofing material which is applied to the roof of the building structure. For example, one known system includes a combination of a reinforced single-ply membrane and a pattern of photovoltaic solar cells. The solar cells are laminated to the membrane and encapsulated in a potting material. A cover layer is applied to the combination for protection. The solar cells are interconnected by conductors, i.e., conductors connect each row in series, with the inner rows being connected to the outer rows by bus bars at one end, and with the other ends terminating in parallel connection bars.

However, known combinations of roofing materials having solar cells can be improved. For example, known combinations of solar cells and roofing typically require multiple internal and external electrical interconnections to be performed on site in order to properly connect all of the solar modules. As a result, substantial wiring, connectors and related hardware are needed to properly wire all of the individual solar cells. Such wiring is typically performed by an electrician rather than a roofer, thereby increasing labor costs and complicating the installation. Additional wire and connection components can also result in composite roofing panels requiring excessive field handling and weight, thereby making storage, transportation, and installation of panels more difficult and expensive. Further, a multitude of interconnections must typically be completed before an installer can run multiple wires or connection lines to an electrical device, a combiner box or an inverter. Also, increasing the number of wires and interconnections in a panel to be installed under field conditions increases the likelihood that the electrical connection in the panel will be broken, e.g., by variables associated with constructive field conditions or wire connections being exposed to inclement weather and/or other hazards (rodents, pigeons, etc.)

Additionally, certain solar modules are encased in a flexible material so as to protect the solar panels in the modules. The flexible material can be, for example, transparent polyimide. Although these transparent materials provide flexibility for the solar modules, the transmission of light through these materials may not be as efficient as, for example, glass. Accordingly, using these flexible materials between the solar rays and the solar modules may reduce the efficiency of such solar modules. Using glass, however, prevents the solar module from being rolled up or folded for storage. Accordingly, glass is not typically used to cover or encase the solar cells of a solar module.

A need, therefore, exists for an integrated photovoltaic roofing component and panel that can be folded into a compact form for transportation to an installation site, and provides for efficient operation.

### SUMMARY

In accordance with an aspect of the disclosure, a photovoltaic panel includes a flexible membrane having a top surface and a bottom surface, a plurality of photovoltaic modules coupled to the top surface of the flexible membrane, and one or more wires in electrical connection with the photovoltaic modules. Each photovoltaic module is spaced apart from an adjacent photovoltaic module by an inter-module gap. The gap is configured to allow any one of the photovoltaic modules to be placed over an adjacent photovoltaic module by folding of the flexible member at the inter-module gap. The wires of each photovoltaic module are connected to wires of adjacent photovoltaic modules. Each wire has a length configured to allow any one of the photovoltaic modules to be placed over an adjacent photovoltaic module by folding of the flexible member at the inter-module gap. The wires pass through the corresponding membrane to connect to the wires of an adjacent photovoltaic module.

In accordance with another aspect of the disclosure, a photovoltaic panel includes a flexible membrane having a top surface and a bottom surface, a plurality of photovoltaic modules coupled to the top surface of the flexible membrane, and one or more wires in electrical connection with the photovoltaic modules. Each photovoltaic module is spaced apart from an adjacent photovoltaic module by an inter-module gap. The gap is configured to allow any one of the photovoltaic modules to be placed over an adjacent photovoltaic module by folding of the flexible member at the inter-module gap. The wires of each photovoltaic module are connected to wires of adjacent photovoltaic modules. Each wire has a length configured to allow any one of the photovoltaic modules to be placed over an adjacent photovoltaic module by folding of the flexible member at the inter-module gap. The plurality of photovoltaic panels are arranged in a rectangular array of at least two columns and at least two rows, each column and each row including at least two photovoltaic modules. The flexible membrane is foldable along a fold line between the two rows of photovoltaic modules and a fold line between the two columns of photovoltaic modules.

In accordance with another aspect of the disclosure, a photovoltaic panel includes a flexible membrane having a top surface and a bottom surface, a plurality of spacers disposed on the top surface of the flexible membrane, at least one photovoltaic module comprising at least one solar cell, the photovoltaic module coupled to the spacers, and at least a pair of electrical wires connected to the photovoltaic module. The spacers provide at least a gap between the photovoltaic module and the flexible membrane.

In accordance with another aspect of the disclosure, a photovoltaic panel includes a flexible membrane having a top surface and a bottom surface, a plurality of photovoltaic modules coupled to the top surface of the flexible membrane, and one or more wires in electrical connection with the photovoltaic modules. Each photovoltaic module is spaced apart from an adjacent photovoltaic module by an inter-module gap. The gap is configured to allow any one of the photovoltaic modules to be placed over an adjacent photovoltaic module by folding of the flexible member at the inter-module gap. The wires of each photovoltaic module are connected to wires of adjacent photovoltaic modules. Each wire has a length configured to allow any one of the photovoltaic modules to be placed over an adjacent photovoltaic module by folding of the flexible member at the inter-module gap. The photovoltaic modules are spaced apart from the flexible membrane by a plurality of spacers to define one or more gaps between the photovoltaic modules and the flexible membrane.

### BRIEF DESCRIPTION OF THE DRAWINGS

FIG. 1 shows a schematic top view of a photovoltaic panel according to the present disclosure.

FIG. 2 shows a cross-sectional view of the photovoltaic panel of FIG. 1 at section line 2-2 of FIG. 1 when the photovoltaic panel is first folded along the fold line B-B and then folded along the fold line A-A.

FIG. 3 shows a cross-sectional view of the photovoltaic panel of FIG. 1 at section line 3-3 of FIG. 1 when the photovoltaic panel is first folded along the fold line B-B and then folded along the fold line A-A.

FIG. 4 shows a schematic diagram of a back side of the photovoltaic panel of FIG. 1.

FIG. 5 shows a schematic diagram of a cross section of a photovoltaic module according to the present disclosure.

FIG. 6 shows a partial cross-sectional view of an embodiment of the photovoltaic panel of FIG. 1.

FIG. 7 shows a partial cross-sectional view of another embodiment of the photovoltaic panel of FIG. 1.

FIG. 8 shows a top view of an alternate embodiment of a photovoltaic panel according to the present disclosure.

FIG. 9 shows a schematic diagram of a back side of the photovoltaic panel of FIG. 8.

FIG. 10 shows a cross-sectional view of the panel of FIG. 8 shown in a folded configuration at section line 10-10.

FIG. 11 shows a perspective view of a flexible membrane according to one embodiment of the present disclosure.

### DETAILED DESCRIPTION

The present disclosure provides a photovoltaic panel (PV). The PV panel includes a plurality of rigid solar or photovoltaic modules (“PV modules”) attached to a flexible membrane. The PV modules are arranged adjacent to each other, e.g., side-by-side, end-to-end or a combination thereof, and are spaced apart from each other so as to allow each PV module to be folded over an adjacent PV module. The folding of the PV modules provides a compact form for the PV panel to aid in storage, transportation and installation of the PV panel. The PV modules have electrical connectors or electrodes that are arranged so as to provide connection to connectors of the adjacent PV modules with wires. The wires extending between adjacent PV modules have sufficient length or slack so as to allow the modules to be folded over each other. The PV panel may include a plurality of spacers between the PV modules and the membrane to provide gaps. The gaps aid in cooling of the PV modules during operation.

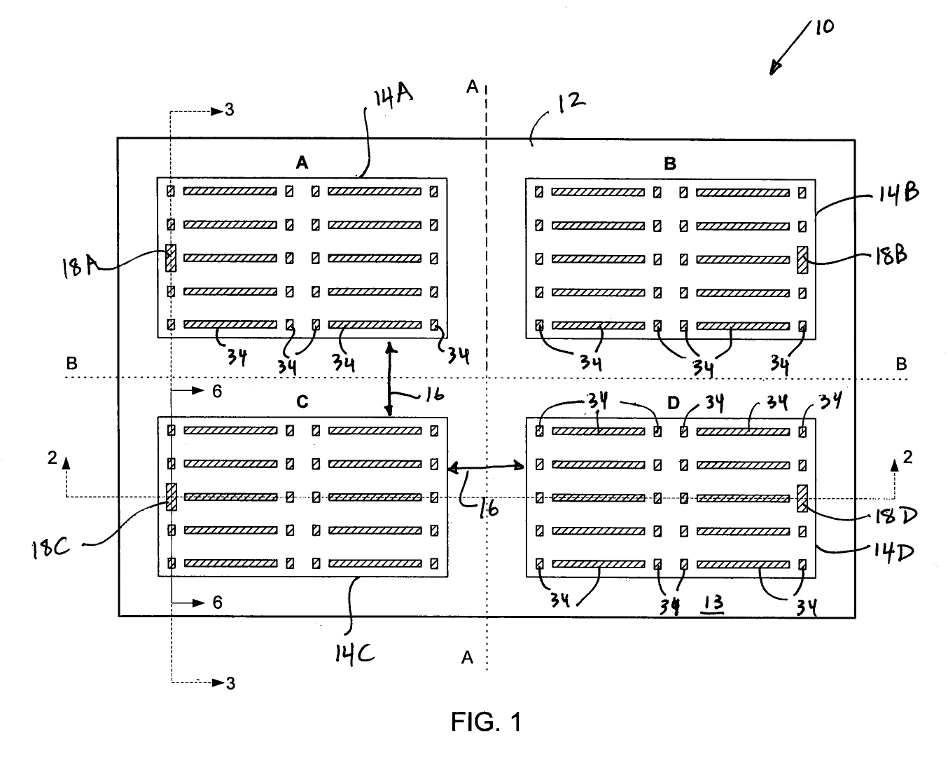

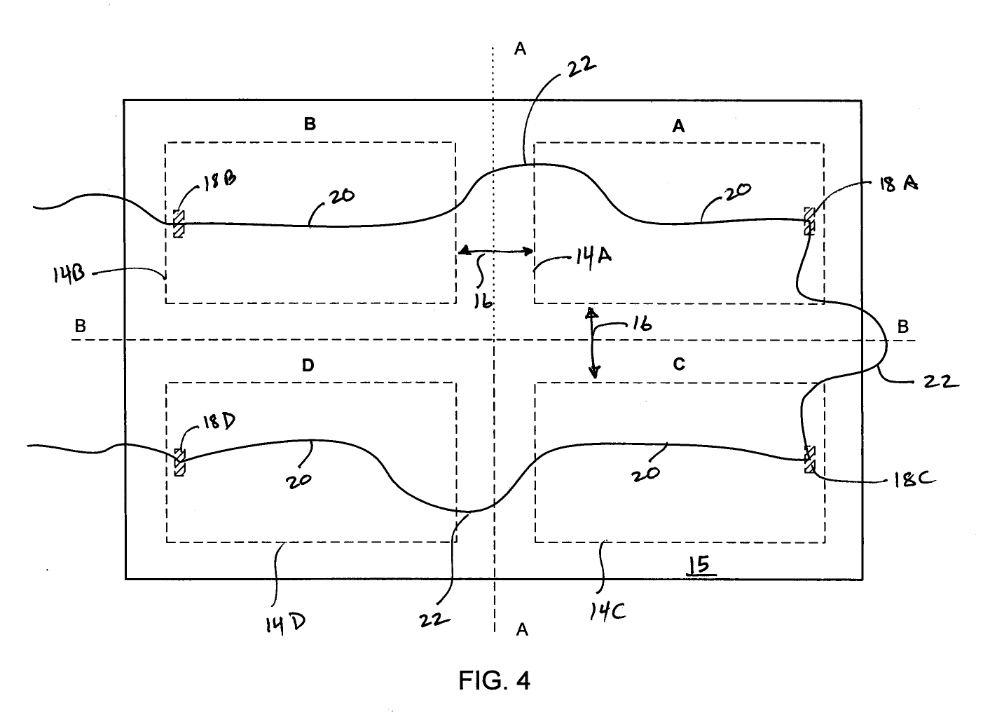

Referring to FIG. 1, a PV panel 10 constructed in accordance with the teachings of the present disclosure is shown. The PV panel 10 includes a flexible base layer or membrane 12 (referred to herein as the membrane 12 or the flexible membrane 12), which includes a top surface 13 and a bottom surface 15 (shown in FIG. 4). The PV panel 10 also includes a plurality of PV modules 14 that are coupled to the top surface 13 of the membrane 12. The PV modules 14 may be arranged on the PV panel 10 in rows, columns or any other arrangement such that an inter-module gap 16 on the membrane 12 is provided between every adjacent PV module 12. The inter-module gap 16 is sized so as to allow the membrane 12 to be folded along the inter-module gap 16. The folding of the membrane 12 along each inter-module gap 16 allows each PV module 12 to be rotated and placed on top of an adjacent PV module 14. Accordingly, a plurality of the PV modules 12 of a PV panel 10 can be placed on top of each other to allow the PV panel 10 to assume a compact shape for transportation, storage and other handling activities that may necessitate a compact form.

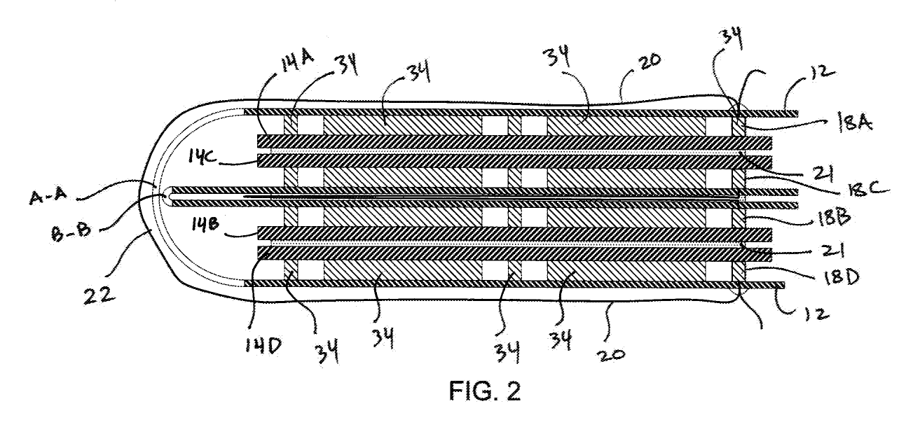

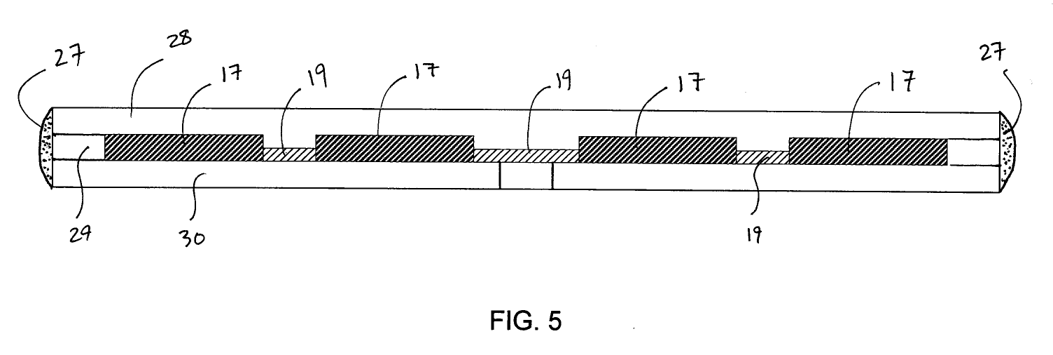

Each PV module 14 includes one or more solar cells 17 (shown in FIG. 5) that are electrically connected to wires, leads, connectors, or the like. The solar cells of the PV module 14 may be connected to adjacent PV modules either directly or through one or more terminal boxes 18. In FIG. 1, each PV module 14 is shown to include a single terminal box 18. However, each PV module 14 may include more than on terminal box 18. Terminal boxes 18 of adjacent PV modules 14 are connected by one or more wires 20 (shown in FIGS. 2-4), which are of sufficient length to allow the herein described folding of the PV panel 10 without stretching and/or breaking the wires, and/or disconnecting the wires from their respective terminal boxes 18. The cables or wires 20 exiting the terminal boxes 18 of the PV modules of a PV panel 10 may be electrically connected in series, parallel or combinations thereof. The PV modules 14 and the solar cells 17 may be of the type that are commercially available, such as Cedarline™ photovoltaic solar cells and modules by Evergreen Solar®, 138 Bartlett Street, Marlboro, Mass. 01752, or KC200GT photovoltaic cells and modules by Kyocera Corporation, 6 Takeda Tobadono-cho, Fushimi-ku, Kyoto, Japan 612-8501.

In FIG. 1, an exemplary arrangement of four PV modules 14A-14D on a PV panel 10 is shown. The PV panel 10 includes four PV modules 14A-14D that are arranged in a two-by-two array on the PV panel 10. The inter-module gaps 16 between the PV modules 14A-14D define two fold lines, which are shown in FIGS. 1 and 4 as fold line A-A and fold line B-B. The PV panel 10 can be folded along fold line A-A and fold line B-B in any order desired so as to provide a compact form for the PV panel 10. The order of folding along the fold lines determines which fold line includes a valley fold (i.e., fold line on the inside of the folded panels), a mountain fold (i.e., fold line on the outside of the folded panels) or a combination of a valley fold and a mountain fold. In FIGS. 1, 4, 8 and 9, a valley fold is shown with a dotted line and a mountain fold is shown with a dashed line.

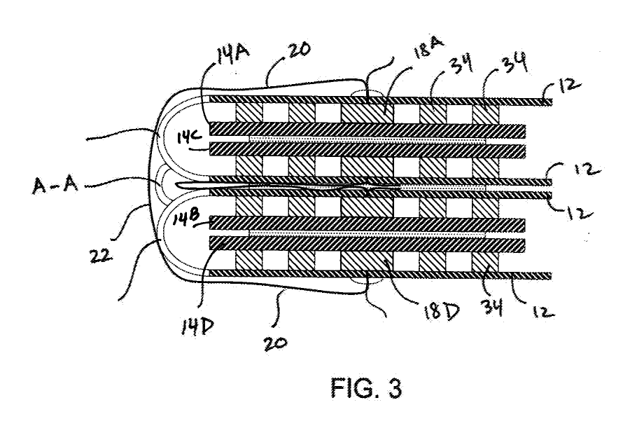

Referring to FIGS. 2 and 3, the PV panel 10 is shown in one exemplary folded configuration. In FIGS. 2 and 3, the PV panel 10 of FIG. 1 is shown to have been valley folded first along the fold line B-B such that PV module 14A faces PV module 14C and PV module 14B faces PV module 14D. The PV panel 10 is then folded along the fold line A-A, such that the back side of PV modules 14A and 14B face each other. Because the PV panel 10 is first folded along the fold line B-B, subsequently folding the PV panel 10 along the fold line A-A creates both a valley fold and a mountain fold along the fold line A-A. Accordingly, the entire fold line B-B represents a valley fold, while the fold line A-A represents both a valley fold and a mountain fold.

FIG. 2 shows a view of the folded PV panel 10 at section line 2-2 of FIG. 1, while FIG. 3 shows a view of the PV panel 10 at section line 3-3 of FIG. 1. However, the PV panel 10 could have been also folded along the fold line A-A first and then along the fold line B-B. To prevent damage to each PV module 14, and in particular, to prevent damage to the outer surface of each PV module 14, a sheet 21 of expanded polystyrene foam (EPS foam) can be placed between each PV module 14 as shown in FIGS. 2 and 3. When the PV panel 10 is folded, it can take a compact form as shown in FIGS. 2 and 3 so as to be easily stored or transported to a site where the PV panel 10 will be used.

Referring to FIG. 4, the back side of the PV panel 10 of FIG. 1 is shown. Each PV module 14 is connected with one or more wires 20 in series, in parallel or any combination thereof so that the electricity generated by each PV module 14 can be transferred out of the PV panel 10. In FIG. 4, the terminal box 18 of each PV module 14 is shown to be connected with a wire 20 to the terminal boxes 18 of adjacent PV module 14 or a Balance-of-Systems (BOS), which may include power electronics (e.g. inverters) or energy storage (e.g. batteries). To provide folding of the PV panel 10 along the fold lines A-A and/or B-B, the length of each wire 20 is longer than the distance between the terminal boxes 18 when the PV panel 10 is in the open configuration as shown in FIG. 1. Accordingly, each wire 20 has a slack or loop 22 when the PV panel 10 is in the open configuration. When the PV panel 10 is folded along any one or both of the fold lines A-A and B-B, as shown in FIGS. 2 and 3, the slack or loop 22 in the wires 20 prevents the wires from stretching, breaking and/or being disconnected from a corresponding terminal box 18. The length of the slack or loop 22 may be determined so as to allow folding of the PV panel 10 along any one of fold lines A-A and B-B in any order desired and with any type of fold (i.e., mountain or valley folds).

Referring to FIG. 5, an exemplary PV module 14 is shown. The PV module 14 may include a top layer 28, a middle layer 29 having one or more solar cells 17 embedded in an appropriate material such as Ethylene-Propylene (EVA) rubber, and an opaque bottom layer 30. The solar cells 17 may be connected with bus bars 19 as is known to those of ordinary skill in the art. The connections between the solar cells 17 may be serial connections, parallel connections or a combination thereof. In the disclosed embodiments, the top layer 28 is constructed from glass or a rigid or semi-rigid material that can provide a level of light transmissivity similar to glass. A semi-rigid material is referred to herein as a material that is flexible but cannot be folded. Such semi-rigid material may be able to flex to a certain limit due to bending and/or torsion, beyond which the material may break or permanently change shape due to plastic deformation. Such semi-rigid materials can include polyvinylidene fluoride (PVDF), ethylene tetrafluoroethylene (ETFE), polyethylene terephthalate (PET) and polyethylene (PE). Although not shown, the rigid or semi-rigid material of the top layer 28 may encase the entire PV module 14 such that it also covers the bottom layer 30. The bottom layer 30 may be constructed from ethylene-propylene (EVA) rubber. Although not shown and described herein, the PV module 14 may include additional layers. For example, the PV module 14 may include another layer (not shown) under the bottom layer 30 that may be constructed from polyvinyl fluoride, such as Dupont Tedlar® layer (e.g., 3 mil thickness). Such additional layers can provide any one of electrical insulation, moisture barrier and bonding layer for incompatible materials. The sides of the PV module 14 may be sealed with side seals 27. The PV module 14 may also be one of commercially available rigid solar modules.

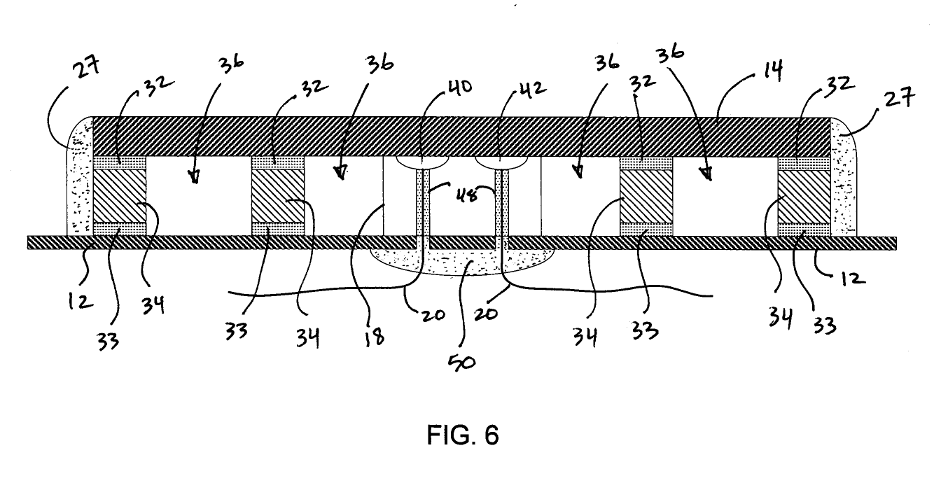

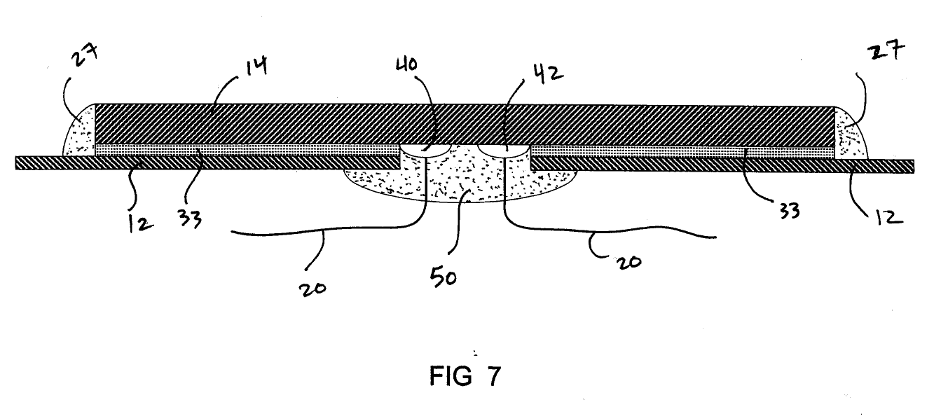

FIGS. 6 and 7 illustrate two embodiments of a PV module 14 having been coupled to the membrane 12. Referring to FIG. 6, to provide additional cooling of the PV module 14 during operation, the PV module 14 is supported by a plurality of spacers 34 (shown also in FIG. 1). The spacers 34 can be constructed of metal such as aluminum, Expandable Polystyrene (EPS) Isocyanurate foam, Polypropylene or other types of rubber and plastic materials. The PV module 14 can be attached to the spacers 34 by an adhesive 32. The spacers 34 can be mounted on the top surface 13 of the membrane 12 by another adhesive 33, which may be the same or different type of adhesive than the adhesive 32. The spacers 34 provide an air gap 36 between the PV module 14 and the membrane 12. The air gap 36 allows air to circulate therein so as to provide cooling of the PV module 14. Additionally, the terminal box 18 of each PV module 14 can function as a spacer 34.

Referring to FIG. 7, the PV module 14 is connected to the top surface 13 of the membrane 12 either directly or through one or more intervening layers such that no gaps are present between the PV module 14 and the top surface 13. Such connection can be facilitated by an adhesive 31 between the PV module 14 and the top surface 13 of the membrane 12. Any heat generated during operation of the PV module 14 can be dissipated by the PV module 14 and transferred to the membrane 12 for dissipation through the membrane 12. The adhesives 31, 32 and 33 of FIGS. 6 and 7 may be the same type or different types of adhesive. One exemplary adhesive that can be used for the adhesives 31, 32 and 33 is a reactive polyurethane hot-melt QR4663, available from Henkel KGaA, Kenkelstrasse 67, 40191 Duesseldorf, Germany.

The PV module 14 may include negative and positive internal electrode soldering pads 40 and 42, respectively. The wires 20 can be soldered to the soldering pads 40 and 42 With the PV module 14 of FIG. 6 the soldering pads 40 and 42 and portions of the wires 20 can be housed in the terminal box 18, which may be a NEMA 4 enclosure. As is known to those of ordinary skill in the art NEMA 4 enclosures provide a degree of protection provide a degree of protection against dirt, rain, sleet, snow, windblown dust, splashing water, hose-directed water; and external formation of ice on the enclosure. All or portions of the wires 20 which are inside or outside the terminal box 18 may include insulation jackets 48. In FIG. 6, the insulation jackets 48 are shown to be only inside the terminal box 18. The PV module 14 of FIG. 7, however, may not include a terminal box such that the soldering pads 40 and 42 are adjacent to the membrane 12 without any gaps or spaces.

As described above, the wires 20 connect the wires of adjacent PV modules 14 or a Balance-of-Systems (BOS). The wires 20 can extend from the soldering pads 40 and 42 through the membrane 12 such that they are disposed beneath the membrane on the backside of the PV panel 10. One exemplary wire 20 that can be used is type XHHW-2 XLP Insulation manufactured by Leviton Mfg. Company Inc., 59-25 Little Neck Pkwy., Little Neck, N.Y. 11362-2591.

The wires 20 extend from the soldering pads 40 and 42 through one or more openings in the membrane 12. In FIG. 6, the membrane 12 is shown to include two apertures 43 that accommodate the passing of the wires 20 through the membrane 12. In FIG. 7, the membrane 12 is shown to include an opening 45 through which the wires 20 pass. Both the apertures 43 of FIG. 6 and the opening 45 of FIG. 7 are examples of providing passing of the wires through the membrane 12. However, any on other type of opening, aperture, or suitable structure can also be used to provide passing of the wires 20 through the membrane 12.

One exemplary flexible membrane 12 that can be used is a single-ply membrane, e.g., an EnergySmart® S327 Roof Membrane, available from Sarnafil, Inc., Roofing and Waterproofing Systems, 100 Dan Road, Canton, Mass. Persons of ordinary skill in the art will recognize that while one exemplary flexible membrane 12 is selected for purposes of explanation and illustration, many other flexible membranes and single-ply membranes can be utilized. For example, alternative single-ply membranes 12 that can be used include flexible polyolefin, modified bitumens which are composite sheets consisting of bitumen, modifiers (APP, SBS) and/or reinforcement such as plastic film, polyester mats, fiberglass, felt or fabrics, vulcanized elastomers or thermosets such as ethyl propylene diene (monomer) terpolymer (EPDM) and non-vulcanized elastomers such as chlorinated polyethylene, chlorosulfonated polyethylene, polyisobutylene, acrylonitrite butadiene polymer.

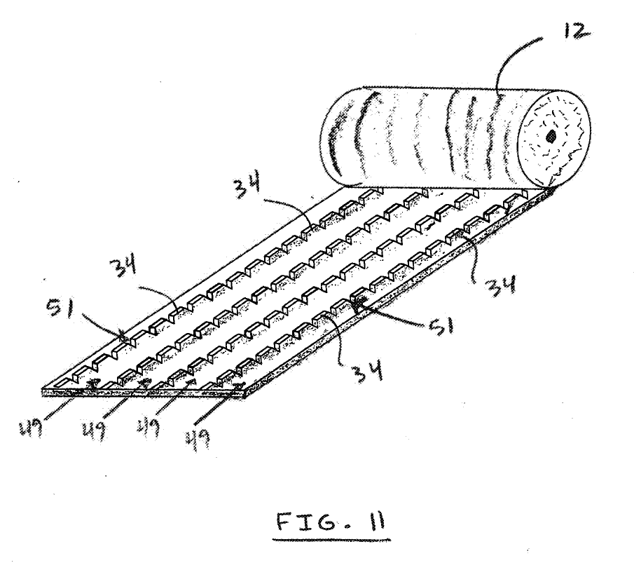

Referring to FIG. 11, the spacers 34 can be integrally formed with the flexible membrane 12. The flexible membrane 12 and the integral spacers 34 form a flexible mat that can be rolled-up for storage and transportation. The spacers 34 can be formed on the flexible membrane 12 in any shape and size desired. Furthermore, the spacers 34 can be formed on the flexible membrane in spaced apart rows and columns. In the example shown in FIG. 11, four rows of spacers 34 are shown, with each row being spaced apart to form a channel 49 between each row. The spacers 34 in each row can also be spaced apart to form channels 51 transverse to each row. The channels 49 and 51 can function as fluid passages for cooling the PV modules 14 and accommodating wires that connect the PV modules 14.

One or more insulative layers 50 (shown in FIGS. 6 and 7) can be applied to the bottom surface 15 of the membrane 12 over an area where the wires 20 extend from the soldering pads 40 and 42 and pass through the membrane 12 to the backside of the PV panel 10 such that the insulative layer 50 covers portions of the wires 20. Accordingly, portions of the wires 20 around the area where the wires extend out from the backside of the PV panel 10 may be encased in the insulative layer 50 When applied to the bottom surface 15 of the membrane 12, the insulative material 50 can be in liquid form prior to curing so as to fill any gaps between the wires 20, the membrane 12, and the terminal box 18. In particular, as shown in FIG. 7, because the PV module 14 may not have a terminal box 18, the insulative layer 50 can fill the gaps around the wires 20 and soldering pads 40 and 42. Accordingly, the insulative material 50 may also function as an insulation jacket for the wires 20 such that using the insulation jacket 48 may not be necessary. The insulative layer 50 may be constructed from a material that can also provide strain relief to portions of the wires 20 during the folding, transportation, unfolding and installation of the PV panel 10. An exemplary insulative layer 50 that can be used is 48 mil S327, available from Sarnafil 100 Dan Road, Canton, Mass. As described above in relation to FIG. 5, the sides of each PV module 14 may include side seals 27. As shown in FIGS. 6 and 7, the side seals 27 may extend to the flexible membrane 12 in order to further seal the sides of the PV module 14 when attached to the membrane 12.

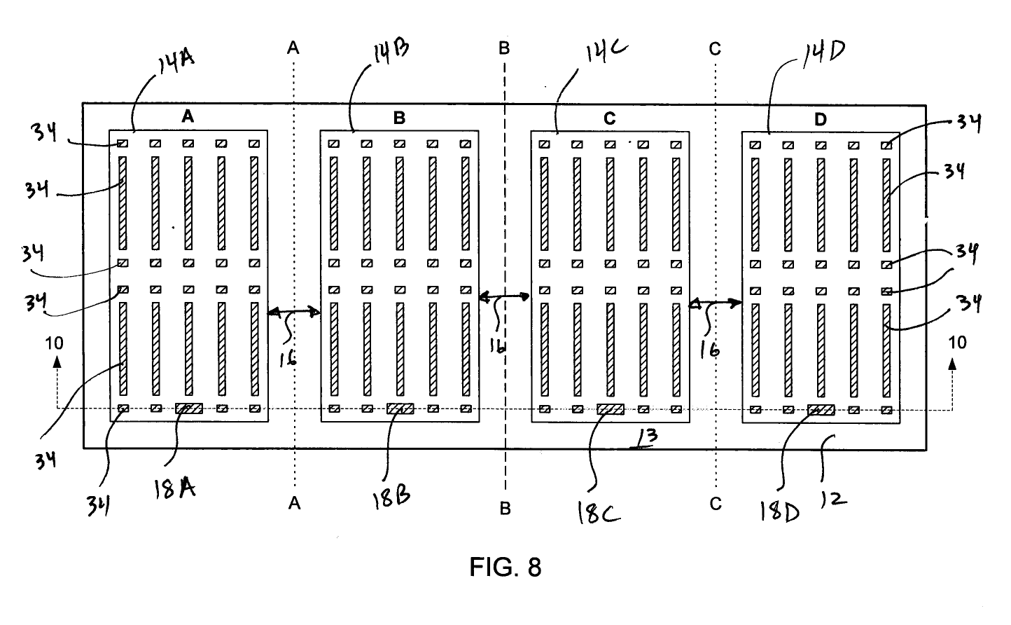

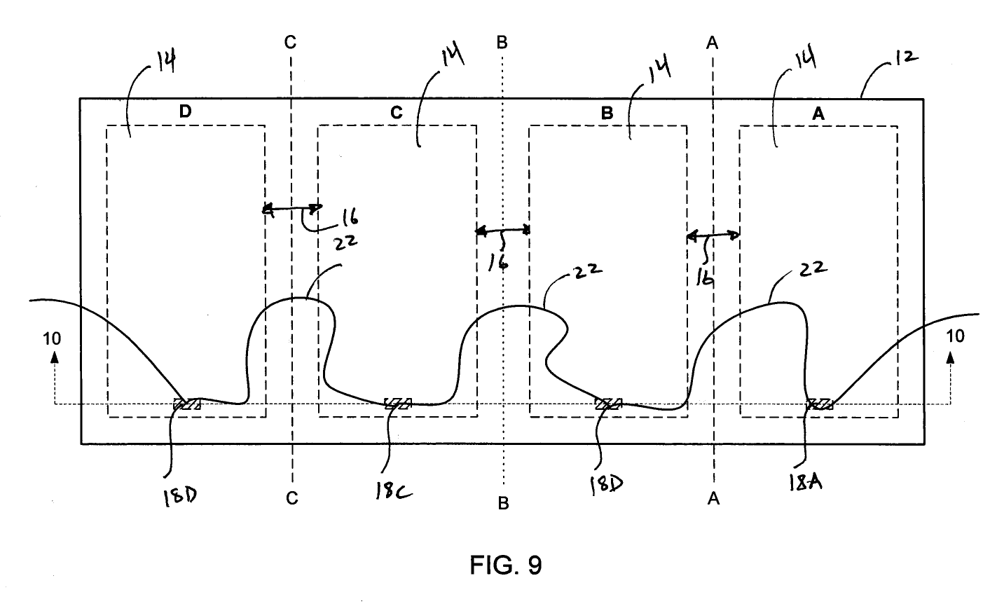

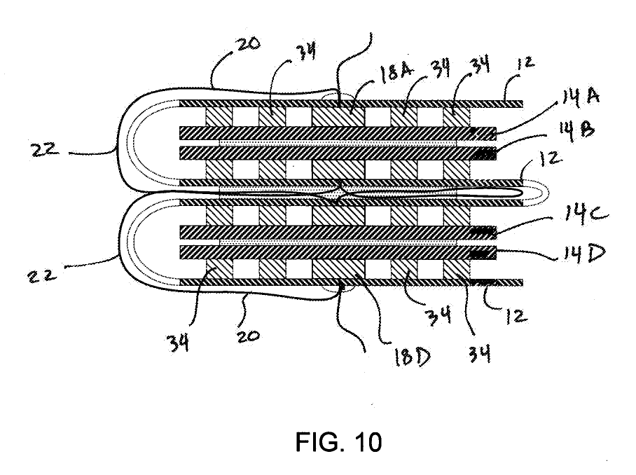

FIG. 8 shows another PV panel 10 which has a different arrangement of PV modules 14. The PV modules 14 are arranged in a row having the inter-module gap 16 between each adjacent PV module 14. As shown in FIG. 9, the wires 20 extend between adjacent terminal boxes 18 of adjacent PV modules 14 to electrically connect the PV modules 14. As described above, each wire 20 includes a slack or loop 22 so as to allow the PV panel 10 to be folded. Referring to FIG. 10, the PV panel 10 is shown to be folded along each of the inter-module gaps 16. Because the PV modules 14 of FIG. 6 are configured in a row on the PV panel 10, the PV modules 14 can be folded on top of each other in a Z-fold manner, which is shown in FIG. 10. In FIG. 8, the PV panel 10 is shown to be folded by a valley fold at fold line A-A, a mountain fold at fold line B-B and a valley fold at fold line C-C to arrive at the folded arrangement shown in FIG. 9. However, the PV panel 10 can be folded with different mountain and fold lines. For example, fold lines A-A and C-C can be a mountain folds and fold line B-B can be a valley fold.

To protect each PV module 14, and in particular to protect the outer surface of each PV module 14 from damage while packing and transporting the PV panel 10, a sheet 21 of expanded polystyrene foam (EPS foam) can be placed between each PV module 14. The folded PV panel 10 assumes a compact form as compared to an unfolded PV panel 10, as shown in FIG. 8, so that it can be packed, transported, and unfolded at a location where one or more PV panels 10 will be used.

When the PV panel 10 is transported to a location for use, such as the roof of a building, the PV panel 10 can be unfolded and attached to the roof using various known techniques (e.g., various adhesives utilized to adhere the flexible PV panel 10 to the substrate or mechanical attachment utilizing screws and plates, combined with hot air welding, solvent welding or radio frequency (RF) welding of the laps or seams. Also, double-sided adhesive tapes, pre-applied adhesive with removable release paper, techniques may be utilized). Each PV panel 10 can also be electrically connected in series, parallel or combinations thereof to one or more other PV panels 10 either directly or through one or more electrical junctions. Exemplary installation and connections of the PV panels 10 are disclosed in U.S. patent application Ser. No. 10/351,299, which is incorporated herein by reference.

The foregoing description of embodiments of the present disclosure has been presented for the purposes of illustration and description. It is not intended to be exhaustive or to limit the disclosure to the precise forms disclosed. Many modifications and variations are possible in light of the above teaching. For example, the integrated photovoltaic roofing panel can be used with many different modules, flexible membranes, adhesives, and arrays of module configurations. Additionally, the integrated photovoltaic component and panel can be used not only as a roofing component, but can also be applied to walls, canopies, tent structures, and other building structures. Further, the integrated photovoltaic roofing panel can be utilized with many different building structures, including residential, commercial and industrial building structures. It is intended that the scope of the disclosure be limited not by this detailed description, but rather by the claims appended hereto.

What is claimed is:

1. A photovoltaic panel, comprising:
a flexible membrane having a top surface and a bottom surface;
a plurality of photovoltaic modules coupled to the top surface of the flexible membrane, each photovoltaic module being spaced apart from an adjacent photovoltaic module by an inter-module gap, the gap configured to allow any one of the photovoltaic modules to be placed over an adjacent photovoltaic module by folding of the flexible member at the inter-module gap; and
one or more wires in electrical connection with the photovoltaic modules, the wires of each photovoltaic module being connected to wires of adjacent photovoltaic modules, each wire having a length configured to allow any one of the photovoltaic modules to be placed over an adjacent photovoltaic module by folding of the flexible member at the inter-module gap;
wherein the wires pass through the corresponding membrane to connect to the wires of an adjacent photovoltaic module.

2. The photovoltaic panel of claim 1, wherein the plurality of photovoltaic panels are arranged in a rectangular array of at least two columns and at least two rows, each column and each row including at least two photovoltaic modules, and wherein the flexible membrane is foldable along a fold line between the two rows of photovoltaic modules and a fold line between the two columns of photovoltaic modules.

3. The photovoltaic panel of claim 2, wherein at least one spacer of each photovoltaic module comprises a terminal box configured to house at least a portion of the wires for the photovoltaic module.

4. The photovoltaic panel of claim 2, wherein the flexible membrane and the spacers are integrally constructed as a one-piece flexible mat.

5. The photovoltaic panel of claim 1, wherein each photovoltaic module includes a plurality of solar cells.

6. The photovoltaic panel of claim 1, further comprising an insulative layer applied to the bottom surface of the flexible membrane to cover at least portions of the wires passing through the corresponding membrane.

7. The photovoltaic panello [symbol] aim 1, wherein a top surface of each photovoltaic module comprises a rigid light transmissive material.

8. The photovoltaic panel of claim 1, wherein a top surface of each photovoltaic module comprises glass.

9. A photovoltaic panel, comprising:
a flexible membrane having a top surface and a bottom surface;
a plurality of photovoltaic modules coupled to the top surface of the flexible membrane, each photovoltaic module being spaced apart from an adjacent photovoltaic module by an inter-module gap, the gap configured to allow any one of the photovoltaic modules to be placed over an adjacent photovoltaic module by folding of the flexible member at the inter-module gap; and
one or more wires in electrical connection with the photovoltaic modules, the wires of each photovoltaic module being connected to wires of adjacent photovoltaic modules, each wire having a length configured to allow any one of the photovoltaic modules to be placed over an adjacent photovoltaic module by folding of the flexible member at the inter-module gap;
wherein the plurality of photovoltaic panels are arranged in a rectangular array of at least two columns and at least two rows, each column and each row including at least two photovoltaic modules; and
wherein the flexible membrane is foldable along a fold line between the two rows of photovoltaic modules and a fold line between the two columns of photovoltaic modules.

10. The photovoltaic panel of claim 9, wherein the photovoltaic modules are spaced apart from the flexible membrane by a plurality of spacers to define one or more gaps between the photovoltaic modules and the flexible membrane.

11. The photovoltaic panel of claim 10, wherein at least one spacer of each photovoltaic module comprises a terminal box configured to house at least a portion of the wires for the photovoltaic module.

12. The photovoltaic panel of claim 10, wherein the flexible membrane and the spacers are integrally constructed as a one-piece flexible mat.

13. The photovoltaic panel of claim 9, wherein each photovoltaic module includes a plurality of solar cells.

14. The photovoltaic panel of claim 9, wherein a top surface of each photovoltaic module comprises a rigid light transmissive material.

15. The photovoltaic panel of claim 9, wherein a top surface of each photovoltaic module comprises glass.

16. A photovoltaic panel, comprising:
a flexible membrane having a top surface and a bottom surface;
a plurality of spacers disposed on the top surface of the flexible membrane;
at least one photovoltaic module comprising at least one solar cell, the photovoltaic module coupled to the spacers; and
at least a pair of electrical wires connected to the photovoltaic module;
wherein the spacers provide at least a gap between the photovoltaic module and the flexible membrane.

17. The photovoltaic panel of claim 16, wherein at least one spacer of each photovoltaic module comprises a terminal box configured to house at least a portion of the wires for the photovoltaic module.

18. The photovoltaic panel of claim 16, wherein the flexible membrane and the spacers are integrally constructed as a one-piece flexible mat.

19. The photovoltaic panello [symbol] aim 16, wherein the wires pass through the membrane to a back side of the membrane, and further comprising an insulative layer applied to the bottom surface of the flexible membrane to cover at least portions of the wires passing through the corresponding membrane.

20. The photovoltaic panel of claim 16, wherein a top surface of the photovoltaic module comprises a rigid light transmissive material.

21. The photovoltaic panel of claim 16, wherein a top surface of at least one photovoltaic module comprises glass.

22. A photovoltaic panel, comprising:
a flexible membrane having a top surface and a bottom surface;
a plurality of spacers coupled to the flexible membrane;
a plurality of photovoltaic modules coupled to the spacers, each photovoltaic module being spaced apart from an adjacent photovoltaic module by an inter-module gap, the gap configured to allow any one of the modules to be placed over an adjacent photovoltaic module by folding of the flexible member at the inter-module gap; and
one or more wires in electrical connection with the photovoltaic modules, the electrical wires of each photovoltaic module being connected to the wires of adjacent photovoltaic modules, each wire having a length configured to allow any one of the photovoltaic modules to be placed over an adjacent photovoltaic module by folding of the flexible member at the inter-module gap;
wherein the photovoltaic modules are spaced apart from the flexible membrane by a plurality of spacers to define one or more gaps between the photovoltaic modules and the flexible membrane.

23. The photovoltaic panel of claim 22, wherein the wires pass through the corresponding membrane to connect to the wires of an adjacent photovoltaic module

24. The photovoltaic panel of claim 22, wherein at least one of the spacers of each photovoltaic module comprises a terminal box configured to house at least portion of wires for the photovoltaic module.

25. The photovoltaic panel of claim 22, wherein the flexible membrane and the spacers are integrally constructed as a one-piece flexible mat.

26. The photovoltaic panel of claim 22, wherein each photovoltaic module includes a plurality of solar cells.

27. The photovoltaic panel of claim 22, further comprising an insulative layer applied to the bottom surface of the flexible membrane to cover at least portions of the wires passing through the corresponding membrane.

28. The photovoltaic panel of claim 22, wherein a top surface of each photovoltaic module comprises a rigid light transmissive material.

29. The photovoltaic panel of claim 22, wherein a top surface of each module comprises glass.
